(19) United States
(12) Patent Application Publication
(10) Pub. No.: US 2025/0308609 A1
(43) Pub. Date: Oct. 2, 2025

(54) MEMORY DEVICE WITH IN-MEMORY COMPUTING BASED ON NON-VOLATILE MEMORY AND METHOD OF OPERATING THE SAME

(71) Applicant: SEOUL NATIONAL UNIVERSITY R&DB FOUNDATION, Seoul (KR)

(72) Inventors: Jae-Joon KIM, Seoul (KR); Munhyeon KIM, Seoul (KR)

(21) Appl. No.: 19/095,178

(22) Filed: Mar. 31, 2025

(30) Foreign Application Priority Data
Apr. 1, 2024 (KR) 10-2024-0044080

(51) Int. Cl. G11C 27/00

(52) U.S. Cl. CPC G11C 27/005

(57) ABSTRACT

A memory device according to one embodiment includes: a memory cell array in which a plurality of unit memories are arranged in an array, each of the unit memory including a first non-volatile memory cell and a second non-volatile memory cell, which store data in a complementary manner, a detection unit that detects the data stored in the first and second non-volatile memory cells for each unit memory; and an operation unit that sets weight data based on output of the detection unit and performs a multiplication operation on input data and the weight data.

### CROSS-REFERENCE TO RELATED APPLICATION

This application claims priority to and the benefit of Korean Patent Application No. 10-2024-0044080 filed in the Korean Intellectual Property Office on Apr. 1, 2024, the entire contents of which are incorporated herein by reference.

### TECHNICAL FIELD

The present disclosure relates to a memory device with in-memory computing based on a non-volatile memory.

### BACKGROUND

Conventional memory devices are classified into static random access memory (SRAM) which is used as cache memory and dynamic random access memory (DRAM) which is used as a main memory. SRAM is used for a high-speed operation, but generally includes six transistors and has low integration. Accordingly, there is a problem of increased area when implementing a high-capacity memory.

In general, DRAM has an 1 Transistor 1 Capacitor (1TIC) cell structure and can be implemented in high capacity and high integration, but has a slower operation speed and shorter retention time than SRAM. Accordingly, there is a problem in that refresh is required at regular intervals even during hold time, not just during read/write operations.

Meanwhile, a non-volatile memory is actively being researched as an alternative to SRAM and DRAM. Basically, the non-volatile memory does not require refreshing and has high integration. However, due to the inherent characteristics of the non-volatile memory, the on/off ratio is limited, which can result in a loss of output information compared to input information in operations that require parallel computation, such as in-memory computing. In-memory computing, also referred to as computing in memory or processing in memory, is a technology that enables the memory to perform computational functions in addition to data storage. In recent years, it has been widely researched as a key technology for implementing AI semiconductors.

When attempting to access a plurality of cells to implement parallel computation for in-memory computing without additional devices, it is highly unlikely to achieve an expected computational accuracy. Conventionally, unit memory cells are modified or additional peripheral circuits are added to perform parallel computation using the non-volatile memory. However, when memory cells are modified, it is highly likely to cause significant reduction in the amount of reusable information per unit area.

Therefore, the present disclosure aims to provide a memory device that enables efficient in-memory computing based on non-volatile memory cells.

As a prior art document related to the present disclosure, there is U.S. Patent Laid-open Publication No. 2023-0259748 (entitled “In-memory computing architecture and methods for performing mac operations”).

### SUMMARY

In view of the foregoing, the present disclosure is conceived to provide a memory device with in-memory computing based on a non-volatile memory cell.

The problems to be solved by the present disclosure are not limited to the above-described problems. There may be other problems to be solved by the present disclosure.

An aspect of the present disclosure provides a memory device including a plurality of memory cells, and the memory device includes: a memory cell array in which a plurality of unit memories are arranged in an array, each of the unit memory including a first non-volatile memory cell and a second non-volatile memory cell, which store data in a complementary manner; a detection unit that detects the data stored in the first and second non-volatile memory cells for each unit memory; and an operation unit that sets weight data based on output of the detection unit and performs a multiplication operation on input data and the weight data.

Another aspect of the present disclosure provides a method of operating a memory device, including: (a) detecting data stored in each unit memory unit from a memory cell array in which a plurality of unit memories are arranged in an array, each of the memory cell units including a first non-volatile memory cell and a second non-volatile memory cell that store data in a complementary manner; (b) setting weight data based on the detected data; and (c) performing a multiplication operation on the weight data and input data.

According to the present disclosure, a simple-structured in-memory computing memory cell can be implemented based on non-volatile memory cells. In particular, a circuit for detecting weight data and a circuit for computing the weight data and input data are arranged separately from the memory cell array. Thus, the overall layout of the memory device can be efficiently configured.

### BRIEF DESCRIPTION OF THE DRAWINGS

In the detailed description that follows, embodiments are described as illustrations only since various changes and modifications will become apparent to a person with ordinary skill in the art from the following detailed description. The use of the same reference numbers in different drawings indicates similar or identical items.

FIG. 1 is a diagram illustrating a memory device according to an embodiment of the present disclosure.

FIG. 2 illustrates a configuration of a memory cell array according to an embodiment of the present disclosure.

FIG. 3 illustrates a configuration of the memory device according to an embodiment of the present disclosure.

FIG. 4 is a waveform diagram illustrating an operation of an arithmetic circuit in the memory device according to an embodiment of the present disclosure.

FIG. 5 illustrates a truth table corresponding to an operation process of the arithmetic circuit in the memory device according to an embodiment of the present disclosure.

FIG. 6 illustrates a configuration of a memory device according to another embodiment of the present disclosure.

FIG. 7 is a waveform diagram illustrating an operation of an arithmetic circuit in the memory device according to an embodiment of the present disclosure.

FIG. 8 illustrates a truth table corresponding to an operation process of the arithmetic circuit in the memory device according to an embodiment of the present disclosure.

FIG. 9 is a flowchart illustrating a method of operating the memory device according to an embodiment of the present disclosure.

### DETAILED DESCRIPTION

Hereafter, embodiments will be described in detail with reference to the accompanying drawings so that the present disclosure may be readily implemented by a person with ordinary skill in the art. However, it is to be noted that the present disclosure is not limited to the embodiments but can be embodied in various other ways. In the drawings, parts irrelevant to the description are omitted for the simplicity of explanation, and like reference numerals denote like parts throughout the whole document.

Throughout this document, the term “connected to” may be used to designate a connection or coupling of one element to another element and includes both an element being “directly connected to” another element and an element being “electronically connected to” another element via another element. Further, throughout the whole document, the term “comprises or includes” and/or “comprising or including” used in the document means that one or more other components, steps, operation and/or existence or addition of elements are not excluded in addition to the described components, steps, operation and/or elements unless context dictates otherwise.

Throughout the whole document, the term “unit” includes a unit implemented by hardware or software and a unit implemented by both of them. One unit may be implemented by two or more pieces of hardware, and two or more units may be implemented by one piece of hardware. However, the “unit” is not limited to the software or the hardware and may be stored in an addressable storage medium or may be configured to implement one or more processors. Accordingly, the “unit” may include, for example, software, object-oriented software, classes, tasks, processes, functions, attributes, procedures, sub-routines, segments of program codes, drivers, firmware, micro codes, circuits, data, database, data structures, tables, arrays, variables and the like. The components and functions provided by the “unit” may be either combined into a smaller number of components and “units” or divided into a larger number of components and “units”. Moreover, the components and “units” may be implemented to reproduce one or more CPUs within a device.

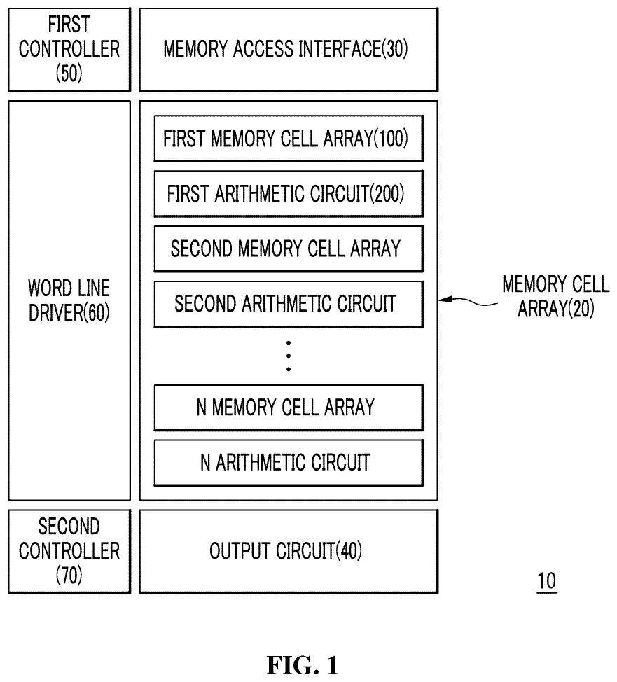

FIG. 1 is a diagram illustrating a memory device according to an embodiment of the present disclosure.

A memory device 10 includes a memory cell array 20 equipped with a plurality of memory cell arrays and a plurality of arithmetic circuits that performs operations on each memory cell array, as well as various peripheral circuits. The peripheral circuits may include a memory access interface 30 that performs a data write or read operation on non-volatile memory cells included in the memory cell array 20, an output circuit 40 that outputs an operation result of the memory cell array 20 to the outside, a first controller 50, a word line driver 60, and a second controller 70. As described later, the output circuit 40 may employ an analog-to-digital converter (ADC) that converts analog output of each arithmetic circuit into digital output or an adder tree that aggregates the digital output of each arithmetic circuit. The first controller 50 controls operations of the non-volatile memory cells included in the memory cell array 20, and the second controller 70 separately controls operations of the arithmetic circuits and various peripheral circuits.

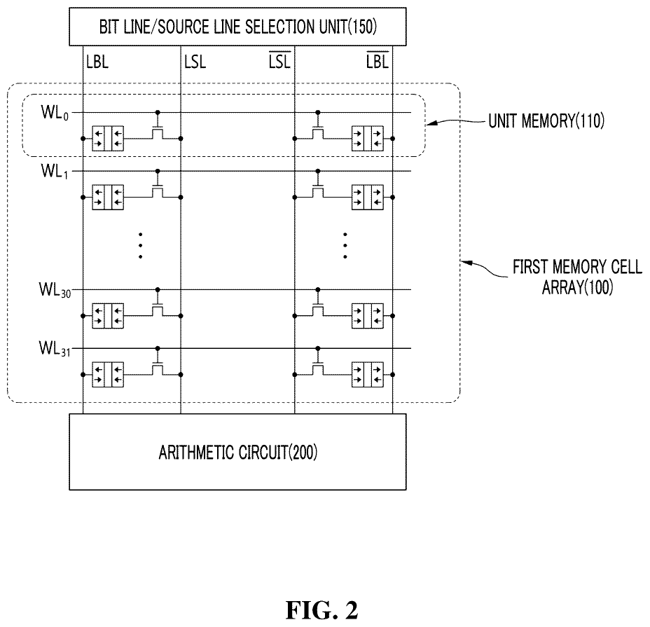

FIG. 2 illustrates a configuration of a memory cell array according to an embodiment of the present disclosure.

The memory cell array 20 includes a plurality of sub-memory cell arrays 100, i.e., first to nth memory cell arrays 100. In the memory cell array 20 or each sub-memory cell array 100 in which a plurality of unit memories 110 are arranged in an array, each of the unit memory 110 including, a first non-volatile memory cell and a second non-volatile memory cell, which store data in a complementary manner. As described above, according to the present disclosure, the first non-volatile memory cell and the second non-volatile memory cell, which store data opposite to each other, form a pair and serve as the unit memory 110. That is, when 0-data is stored in the first non-volatile memory cell, 1-data is stored in the second non-volatile memory cell, and vice versa. The data stored in the unit memory 110 may be used as weight data.

Further, as shown in FIG. 2, a plurality of unit memories 110 is arranged along bit lines LBL and /LBL and source lines LSL and /LSL, and the plurality of unit memories 110 operates as sub-memory cell arrays 100. In the present disclosure, an arithmetic circuit 200 is connected to each sub-memory cell array 100. The arithmetic circuit 200 detects the data stored in each unit memory 110, selects weight data based on the detected data, and performs a multiplication operation on the weight data and input data. The input data may be activation data for each layer forming a deep neural network, and the weight data may be weight values forming a trained artificial intelligence model or deep neural network model.

A bit line/source line selection unit 150 supplies predetermined bit line or source line signals to the plurality of bit lines or source lines connected to each memory cell array.

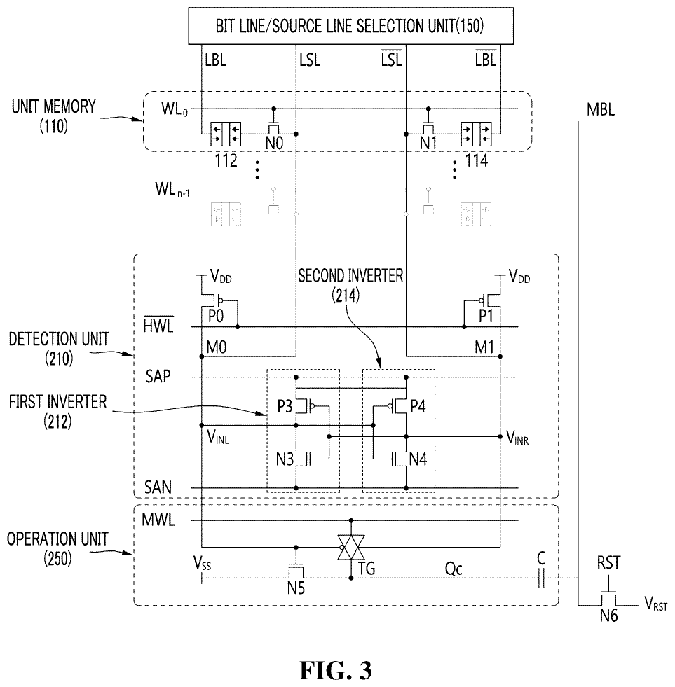

FIG. 3 illustrates a configuration of the memory device according to an embodiment of the present disclosure.

The unit memory 110 may include a first switching element N0 which is switched by a word line signal WL and of which the other end is connected to a first source line LSL and a second switching element N1 which is switched by the word line signal WL and of which the other end is connected to a second source line /LSL. Herein, the second source line /LSL is applied with an inverted signal of the signal applied to the first source line LSL. The unit memory 110 may further include a first non-volatile memory cell 112 of which one end is connected to a first bit line LBL and the other end is connected to one end of the first switching element N0 and a second non-volatile memory cell 114 of which one end is connected to a second bit line /LBL and the other end is connected to one end of the second switching element N1. The second bit line /LBL is applied with an inverted signal of the signal applied to the first bit line LBL.

A magnetic random access memory (MRAM) may be used as a non-volatile memory cell, and other types of non-volatile memories, such as memristor, ReRAM, PCRAM, RRAM, PCRAM, and FEFET, may also be used. Further, NMOS may be used as the first switching element N0 and the second switching element N1, but other types of switching elements may also be used.

By adjusting a voltage applied to the word lines, bit lines, and source lines in this configuration, read and write operations can be performed on each non-volatile memory. Specific details of the read and write operations depend on the type of non-volatile memory and are based on conventional technologies. Therefore, detailed descriptions thereof are omitted herein.

In the present disclosure, during a process of detecting data stored in each non-volatile memory, a specific word line (WL) signal capable of selecting a specific unit memory is applied to turn on the first switching element N0 and the second switching element N1 connected to the word line. Further, information on the state of each non-volatile memory cell is transferred to the arithmetic circuit 200 via the first source line LSL and the second source line /LSL.

The arithmetic circuit 200 includes a detection unit 210 that detects the data stored in the first non-volatile memory cell 112 and the second non-volatile memory cell 114 for each unit memory 110, and an operation unit 250 that selects weight data from output of the detection unit 210 and performs a multiplication operation on the input data and the weight data.

The detection unit 210 may include latches that amplify the data stored in the first non-volatile memory cell 112 and the second non-volatile memory cell 114 and output a first amplified value and a second amplified value, respectively. The latches may be composed of a first inverter 212 and a second inverter 214 arranged in a back-to-back structure.

Also, the detection unit 210 may include a first pull-up switching element P0 and a second pull-up switching element P1, which are switched by a horizontal word line signal /HWL and of which one ends are connected to a power supply voltage. Herein, the other end of the first pull-up switching element P0 is connected to an output node of the first inverter 212 to form a first node M0, and the other end of the second pull-up switching element P1 is connected to an output node of the second inverter 214 to form a second node M1. Accordingly, the output of the first non-volatile memory cell 112 is applied to the output node of the first inverter 212 and the first node M0 through the first source line LSL, and the output of the second non-volatile memory cell 114 is applied to the output node of the second inverter 214 and the second node M1 through the second source line /LSL. Meanwhile, PMOS transistors may be used as the first pull-up switching element P0 and the second pull-up switching element P1, but other types of switching elements may also be used.

The output of the first non-volatile memory cell 112 is input to an input node of the second inverter 214 via the output node of the first inverter 212, and the output of the second non-volatile memory cell 114 is input to an input node of the first inverter 212 via the output node of the second inverter 214. Thus, the output of each non-volatile memory cell is amplified depending on the operation of the inverter. Through this process, the output node of the first inverter 212 outputs a first amplified value V_{INL}, and the output node of the second inverter 214 outputs a second amplified value V_{INR}.

Meanwhile, the first inverter 212 and the second inverter 214 are CMOS inverters in which PMOS and NMOS transistors are connected in series, and driving signals for operating respective inverters are applied as a first control signal SAP and a second control signal SAN. That is, as shown in FIG. 3, the first control signal SAP is applied to one ends of the PMOS transistors of the first inverter 212 and the second inverter 214, and the second control signal SAN is applied to the other ends of the NMOS transistors of the first inverter 212 and the second inverter 214. Connection nodes of the PMOS and NMOS transistors function as output nodes, and gates of the PMOS and NMOS transistors are connected to function as input nodes.

The operation unit 250 may include a transfer gate TG that is switched by the first amplified value V_{INL} and the second amplified value V_{INR} output by the detection unit 210 and configured to transfer a signal of an operation word line MWL to which input data is applied, a capacitor C that is charged with charges transferred by the transfer gate TG, and a ground switching element N5 that is switched by the first amplified value and selectively grounds one end of the capacitor C. The capacitor C may output an operation result of the operation unit 250 through capacitive coupling.

The transfer gate TG includes a first gate, a second gate, an input end, and an output end. The first amplified value may be applied to the first gate, the second amplified value may be applied to the second gate, and the input data may be input to the input end. According to the present disclosure, when the first amplified value is applied to the first gate and the second amplified value is applied to the second gate, if the first amplified value is low-level data and the second amplified value is high-level data, the transfer gate is turned on.

Further, while the transfer gate TG is turned on, the charge amount of the capacitor C may be determined according to the input data applied through the operation word line MWL. That is, when the input data is 1-data, the capacitor C may be charged with high-level charges, and when the input data is 0-data, the capacitor C may not be charged. Furthermore, when the first amplified value is high-level data, the ground switching element N5 may be turned on and a ground voltage VSS connected to one side of the ground switching element N5 may be connected to the capacitor C connected to the other side of the ground switching element N5.

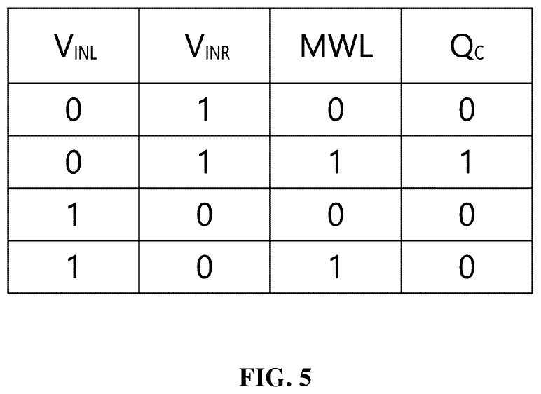

Meanwhile, the arithmetic circuit 200 may receive output of a plurality of unit memories connected along the source lines and bit lines, and the output is accumulated and then output through operation bit lines MBL. That is, the amounts of charges in the capacitors C of a plurality of operation units 250 are accumulated in the operation bit lines MBL, and the values accumulated in the operation bit lines may be used as output of multiply-accumulate operations MAC. As such, the operation unit 250 according to the embodiment shown in FIG. 3 utilizes capacitive coupling characteristics of the capacitor and can be classified as an analog operation unit 250, unlike the embodiment shown in FIG. 5.

Further, the output circuit 40 may employ an ADC that converts analog values accumulated in the operation bit line MBL into digital values.

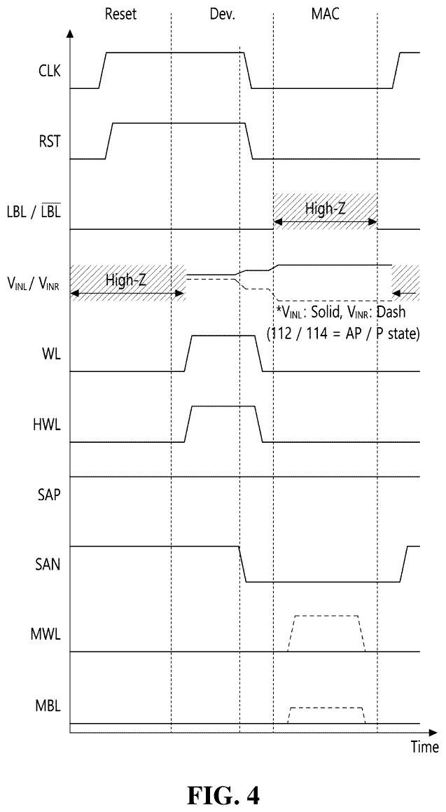

FIG. 4 is a waveform diagram illustrating an operation of an arithmetic circuit in the memory device according to an embodiment of the present disclosure, and FIG. 5 illustrates a truth table corresponding to an operation process of the arithmetic circuit in the memory device according to an embodiment of the present disclosure.

As shown in FIG. 4, the overall operation can be broadly divided into a reset phase Reset, a development phase Dev., and a MAC operation phase MAC.

First, during the reset phase, the word line signal WL is maintained at a low level to ensure that the first switching element N0 and the second switching element N1 of the unit memory 110 remain off. Also, a horizontal word line signal HWL of the detection unit 210 is maintained at a low level to ensure that the first pull-up switching element P0 and the second pull-up switching element P1 remain off. Further, high-level signals are applied as the first control signal SAP and the second control signal SAN to maintain the first inverter 212 and the second inverter 214 of the detection unit 210 in their initial states.

Then, during the development phase, the data stored in the first non-volatile memory cell 112 and the second non-volatile memory cell 114 is transferred to the detection unit 210, which then detects and amplifies these values. To this end, the word line signal WL is switched to a high level for a predetermined period of time to turn on the first switching element N0 and the second switching element N1 of the unit memory 110. Similarly, the horizontal word line signal HWL of the detection unit 210 is also switched to a high level for a predetermined period of time to turn on the first pull-up switching element P0 and the second pull-up switching element P1. Consequently, each of the first node M0 and the second node M1 is pulled up to the power supply voltage, and, thus, the data from the first non-volatile memory cell 112 and the data from the second non-volatile memory cell 114 may be transferred through the first source line LSL and the second source line /LSL to the first node M0 and the second node M1, respectively.

If the non-volatile memory cells 112 and 114 are resistive memory cells, their data may be classified as HRS (AP, 0-data) or LRS (P, 1-data). Therefore, if 0-data is stored in the first non-volatile memory cell 112 and 1-data is stored in the second non-volatile memory cell 114, a voltage at the first node MO can be measured as higher than that at the second node M1. Conversely, if 1-data is stored in the first non-volatile memory cell 112 and 0-data is stored in the second non-volatile memory cell 114, the voltage at the second node M1 can be measured as higher than that at the first node M0. However, a voltage difference between the first node M0 and the second node M1 may not be significant, and, thus, a process of amplifying the voltage difference is required.

During the latter half of the development phase Dev., when the word line signal WL and the horizontal word line signal HWL are switched back to low levels, the first switching element N0 and the second switching element N1 of the unit memory 110 are turned off again and the first pull-up switching element P0 and the second pull-up switching element P1 of the detection unit 210 are also turned off. Thus, the data transfer from the non-volatile memory cells via the source lines is stopped. Then, when the second control signal SAP applied to each of the inverters 212 and 214 is switched to a low level, the first inverter 212 and the second inverter 214 begin to operate. Thus, the voltage difference between the first node MO and the second node M1 is amplified. As a result, the first inverter 212 and the second inverter 214 output the first amplified value V_{INL} and the second amplified value V_{INR}, respectively.

Thereafter, during the MAC operation phase, input data is applied through the operation word line MWL. As shown in FIG. 5, if 0-data is stored in the first non-volatile memory cell 112 and 1-data is stored in the second non-volatile memory cell 114, the first amplified value V_{INL} is output as high-level data and the second amplified value V_{INR} is output as low-level data. Consequently, the transfer gate TG is turned off, and the capacitor C remains in a discharged state.

Conversely, if 1-data is stored in the first non-volatile memory cell 112 and 0-data is stored in the second non-volatile memory cell 114, the first amplified value V_{INL} is output as low-level data and the second amplified value V_{INR} is output as high-level data. Consequently, the transfer gate TG may be turned on. Further, since the transfer gate TG is turned on, the input data is transferred through the operation word line MWL. Thus, the capacitor C can be charged or discharged depending on the input data. Therefore, according to the present disclosure, whether or not to turn on the transfer gate TG is determined based on the data stored in the first and second non-volatile memory cells 112 and 114 included in the unit memory 110. Thus, the data stored in the first and second non-volatile memory cells 112 and 114 in a complementary manner can substantially function as weight data.

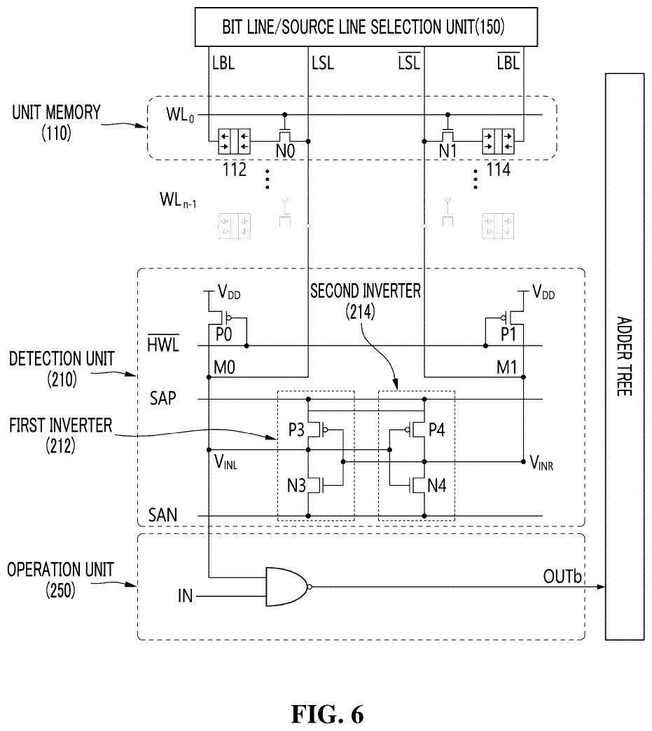

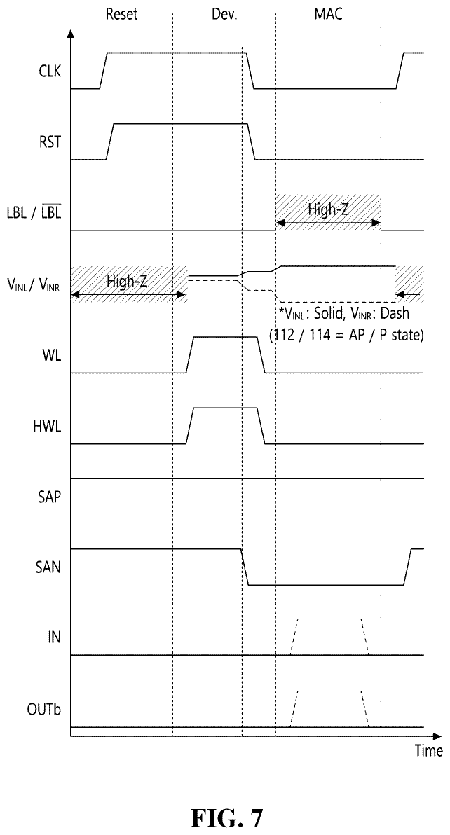

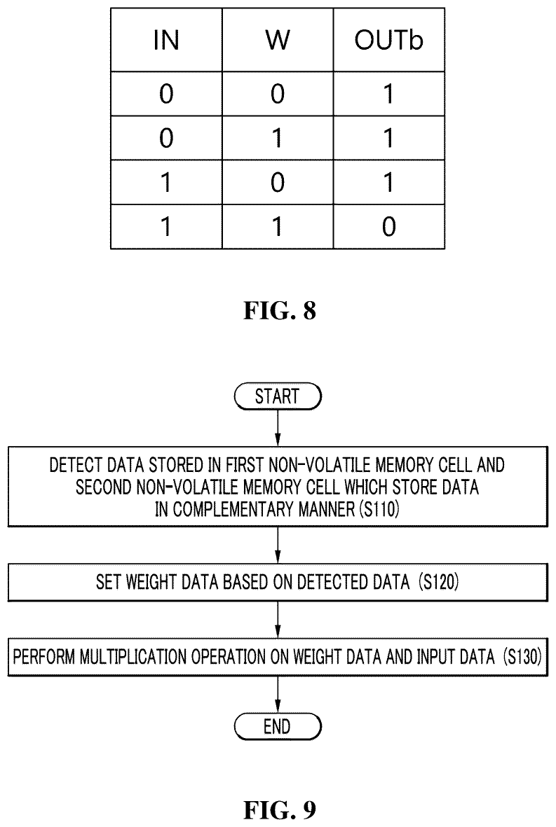

FIG. 6 illustrates a configuration of a memory device according to another embodiment of the present disclosure, FIG. 7 is a waveform diagram illustrating an operation of an arithmetic circuit in the memory device according to an embodiment of the present disclosure, and FIG. 8 illustrates a truth table corresponding to an operation process of the arithmetic circuit in the memory device according to an embodiment of the present disclosure.

The overall configuration of the memory device is the same as in the embodiment of FIG. 3 except a configuration of an operation unit 250′. Unlike the embodiment shown in FIG. 3, the operation unit 250′ performs multiplication through digital computations. The operation unit 250′ may select a value detected by the detection unit as weight data based on the data stored in the first non-volatile memory cell. Further, the operation unit 250′ may include a NAND gate that receives input data IN and weight data W as input.

As described above, during the development phase Dev., the detection unit 210 enables the first inverter 212 and the second inverter 214 to output the first amplified value V_{INL} and the second amplified value V_{INR}, respectively, based on the data stored in the first non-volatile memory cell 112 and the second non-volatile memory cell 114. Particularly, the first amplified value V_{INL} can be input to the NAND gate as the weight data W.

The waveform diagram shown in FIG. 7 is almost identical to that in FIG. 6, and confirms that output OUTb of the NAND gate is used for the MAC operation. Also, as shown in the truth table of FIG. 8, a result of NAND operations on the weight data W and the input data IN is output.

Since a value output by the NAND gate of the operation unit 250′ is digital data, a different type of output circuit 40 may be used, compared to the embodiment shown in FIG. 3. That is, an adder tree may be used to accumulate values output by each operation unit 250′. According to general in-memory computing technologies, a memory that performs computations can be implemented in the form of a systolic array including processing elements PEs. Each PE performs multiplication, aggregates the result with an output value (partial sum) from the previous PE, and transfers the sum to the next PE, and the adder tree is used to aggregate the partial sums into a final sum. The adder tree aggregates output of the plurality of operation units 250′ by using a plurality of adders arranged in a hierarchical or tree structure and thus enables output of multiply-accumulate operations. The detailed configuration of the adder tree pertains to the prior art. Therefore, additional descriptions thereof are omitted herein.

FIG. 9 is a flowchart illustrating a method of operating the memory device according to an embodiment of the present disclosure.

First, data stored in each unit memory is detected from the memory cell array 100 in which which a plurality of unit memories 110 are arranged in an array, each of the unit memory 110 including, a first non-volatile memory cell and a second non-volatile memory cell, which store data in a complementary manner (S110). As shown in FIG. 4 or FIG. 7, this process may be performed during the former half of the development phase by applying the word line signal WL and the horizontal word line signal HWL as high-level data.

Then, weight data is set based on the detected data (S120). To this end, this process may be performed during the latter half of the development phase by switching the word line signal WL and the horizontal word line signal HWL to low levels, driving a first inverter and a second inverter, which are arranged in a back-to-back structure, and outputting a first amplified value and a second amplified value.

As shown in FIG. 3, when the operation unit 250 performs analog computations, the first amplified value and the second amplified value are applied to a first gate and a second gate, respectively, of the transfer gate TG to selectively activate the transfer gate based on the first amplified value and the second amplified value. When the transfer gate TG is activated, the weight data is set to 1. When the transfer gate TG is turned off, the weight data is set to 0.

Further, as shown in FIG. 4, when the operation unit 250′ performs digital computations, the first amplified value is applied to a NAND gate as first input.

Then, a multiplication operation is performed on the weight data and input data (S130).

As shown in FIG. 3, when the operation unit 250 performs analog computations, the input data applied to an input end of the transfer gate is output to an output end of the transfer gate depending on whether the transfer gate is activated. The output of the transfer gate may charge a capacitor connected to the output end of the transfer gate through capacitive coupling and is accumulated and then output as a result of MAC operations.

As shown in FIG. 4, when the operation unit 250′ performs digital computations, the input data is applied to the NAND gate as second input, and NAND operations are performed on the input data as well as the weight data applied as the first input. The output of the NAND gate is aggregated by an adder tree and then output as a result of MAC operations.

The method according to an embodiment of the present disclosure can be embodied in a storage medium including instruction codes executable by a computer such as a program module executed by the computer. A computer-readable medium can be any usable medium which can be accessed by the computer and includes all volatile/non-volatile and removable/non-removable media. Further, the computer-readable medium may include computer storage media. The computer storage media include all volatile/non-volatile and removable/non-removable media embodied by a certain method or technology for storing information such as computer-readable instruction code, a data structure, a program module or other data.

The method and system of the present disclosure have been explained in relation to a specific embodiment, but their components or a part or all of their operations can be embodied by using a computer system having general-purpose hardware architecture.

The above description of the present disclosure is provided for the purpose of illustration, and it would be understood by a person with ordinary skill in the art that various changes and modifications may be made without changing technical conception and essential features of the present disclosure. Thus, it is clear that the above-described examples are illustrative in all aspects and do not limit the present disclosure. For example, each component described to be of a single type can be implemented in a distributed manner. Likewise, components described to be distributed can be implemented in a combined manner.

The scope of the present disclosure is defined by the following claims rather than by the detailed description of the embodiment. It shall be understood that all modifications and embodiments conceived from the meaning and scope of the claims and their equivalents are included in the scope of the present disclosure.

### EXPLANATION OF CODES

10: Memory device
100: Memory cell
110: Non-volatile memory cell
120: First switching clement
130: Inverter
140: Capacitor

What is claimed is:

1. A memory device including a plurality of memory cells, comprising:
a memory cell array in which a plurality of unit memories are arranged in an array, each of the unit memory including a first non-volatile memory cell and a second non-volatile memory cell, which store data in a complementary manner;
a detection unit that detects the data stored in the first and second non-volatile memory cells for each unit memory; and
an operation unit that sets weight data based on output of the detection unit and performs a multiplication operation on input data and the weight data.

2. The memory device of claim 1,
wherein the unit memory includes:
a first switching element which is switched by a word line signal and of which the other end is connected to a first source line;
a second switching element which is switched by the word line signal and of which the other end is connected to a second source line;
a first resistive memory cell of which one end is connected to a first bit line LBL and the other end is connected to one end of the first switching element; and
a second resistive memory cell of which one end is connected to a second bit line and the other end is connected to one end of the second switching element, and
the second source line is applied with an inverted signal of the signal applied to the first source line,
the second bit line is applied with an inverted signal of the signal applied to the first bit line, and
the first resistive memory cell and the second resistive memory cell store data in a complementary manner.

3. The memory device of claim 1,
wherein the detection unit includes latches that amplify the data stored in the first non-volatile memory cell and the second non-volatile memory cell and output a first amplified value and a second amplified value, respectively.

4. The memory device of claim 3,
wherein the detection unit includes:
a first pull-up switching element and a second pull-up switching element, which are switched by a horizontal word line signal and of which one ends are connected to a power supply voltage; and
a first inverter included in the latch and configured to receive the second amplified value and output the first amplified value and a second inverter configured to receive the first amplified value and output the second amplified value,
the other end of the first pull-up switching element is connected to an output node of the first inverter and the other end of the second pull-up switching element is connected to an output node of the second inverter,
output of the first non-volatile memory cell is applied to the output node of the first inverter, and output of the second non-volatile memory cell is applied to the output node of the second inverter, and
a first control signal and a second control signal are applied as signals for driving the first inverter and the second inverter.

5. The memory device of claim 4,
wherein the operation unit includes:
a transfer gate that is switched by the first amplified value and the second amplified value and configured to transfer a signal of an operation word line to which the input data is applied;
a capacitor that is charged with charges transferred by the transfer gate; and
a ground switching element that is switched by the first amplified value and selectively grounds one end of the capacitor.

6. The memory device of claim 5,
wherein when the first amplified value is low-level data and the second amplified value is high-level data, the transfer gate is turned on, and while the transfer gate is turned on, the charge amount of the capacitor is determined according to the input data applied through the operation word line, and
when the first amplified value is high-level data, the ground switching element is turned on and the capacitor is discharged.

7. The memory device of claim 6,
wherein the amounts of charges in capacitors of a plurality of operation units are accumulated in operation bit lines, and values accumulated in the operation bit lines are used as output of multiply-accumulate operations.

8. The memory device of claim 1,
wherein the operation unit selects, as the weight data, the value detected by the detection unit based on the data stored in the first non-volatile memory cell, and
the operation unit includes a NAND arithmetic circuit that receives the input data and the weight data as input.

9. The memory device of claim 4,
wherein during a reset phase, the first switching element and the second switching element of the unit memory are turned off, the first pull-up switching element and the second pull-up switching element of the detection unit are turned off, and the first inverter and the second inverter of the detection unit are maintained in their initial states.

10. A method of operating a memory device, comprising:
(a) detecting data stored in each unit memory unit from a memory cell array in which a plurality of unit memories are arranged in an array, each of the memory cell units including a first non-volatile memory cell and a second non-volatile memory cell that store data in a complementary manner;
(b) setting weight data based on the detected data; and
(c) performing a multiplication operation on the weight data and input data.

11. The method of claim 10,
wherein in the process (a), the data detected from the first non-volatile memory cell and the data detected from the second non-volatile memory cell are input to a first inverter and a second inverter which are arranged in a back-to-back structure, and a value output from the first inverter is output as a first amplified value and a value output from the second inverter is output as a second amplified value.

12. The method of claim 11,
wherein in the process (b), the first amplified value and the second amplified value are applied to a first gate and a second gate, respectively, of a transfer gate to selectively activate the transfer gate depending on the first amplified value and the second amplified value, and
in the process (c), the input data applied to an input end of the transfer gate is output to an output end of the transfer gate depending on whether the transfer gate is activated.

13. The method of claim 12,
wherein the output of the transfer gate charges a capacitor connected to the output end of the transfer gate through capacitive coupling.

14. The method of claim 11,
wherein in the process (b), the first amplified value is applied to a NAND gate as first input, and
in the process (c), the input data is applied to the NAND gate as second input.

15. The method of claim 14,
wherein output of the NAND gate is input to an adder tree.
